(19) United States
(12) Patent Application Publication
(10) Pub. No.: US 2026/0308764 A1
(43) Pub. Date: Oct. 8, 2026

(54) TOMBSTONE STRUCTURE SYSTEMS AND METHODS

(71) Applicant: ASM IP Holding B.V., Almere (NL)

(72) Inventors: Bikram Panda, Gilbert, AZ (US); Ankit Kimtee, Phoenix, AZ (US); Dohan Kim, Phoenix, AZ (US); Petri Raisanen, Gilbert, AZ (US); Jereld Lee Winkler, Gilbert, AZ (US)

(21) Appl. No.: 19/635,919

(22) Filed: Apr. 1, 2026

Related U.S. Application Data
(60) Provisional application No. 63/783,886, filed on Apr. 4, 2025.

(51) Int. Cl. C23C 16/455

(52) U.S. Cl. CPC C23C 16/45563

(57) ABSTRACT

An outlet passage having a first portion having a first diameter and a second portion having a second diameter, the first diameter being from about one to about 3 times the second diameter, a transition portion disposed between the first portion and the second portion, the transition portion having a chamfer feature that is disposed at an angle between about 20 degrees and about 35 degrees from an outer wall of the second portion.

### CROSS-REFERENCE TO RELATED APPLICATIONS

This application is a nonprovisional of, and claims priority to and the benefit of, U.S. Provisional Patent Application No. 63/783,886, filed Apr. 4, 2025 and entitled “TOMBSTONE STRUCTURE SYSTEMS AND METHODS,” which is hereby incorporated by reference herein.

### FIELD

The present disclosure generally relates to gas flow systems and components thereof. More particularly, the disclosure relates to systems and methods for effective precursor gas flow.

### BACKGROUND OF THE DISCLOSURE

Gas-phase reactors can be used for a variety of applications, such as chemical vapor deposition (CVD), plasma-enhanced CVD (PECVD), atomic layer deposition (ALD), plasma-enhanced ALD (PEALD), substrate precleaning, etch processes, and the like. For example, gas-phase reactors can be used to deposit material, etch layers, and/or clean material on a substrate to form electronic devices, such as semiconductor devices, flat panel display devices, photovoltaic devices, microelectromechanical systems (MEMS), and the like.

A typical gas-phase reactor system includes one or more reactors, each reactor including a reaction chamber and one or more gas sources fluidly coupled to the reaction chamber. In many applications, such as ALD, PEALD, and other cyclical processes, precursor gases flow through various components and passageways. Changes in precursor gas flow characteristics may tend to cause condensation and/or deposition of precursor material, which is typically undesirable.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY OF THE DISCLOSURE

Various embodiments of the present disclosure relate to an outlet passage comprising a first portion having a first diameter and a second portion having a second diameter, the first diameter being from about one to about 3 times the second diameter, a transition portion disposed between the first portion and the second portion, the transition portion having a chamfer feature that is disposed at an angle between about 20 degrees and about 35 degrees from an outer wall of the second portion.

In various embodiments, a length of the transition portion is from about one to about three times the second diameter.

In various embodiments, the outlet passage is formed in a monolithic block.

In various embodiments, the outlet passage further comprises a gasket at least partially surrounding the outlet passage.

In various embodiments, the chamfer feature extends about a circumference of the transition portion.

In various embodiments, the chamfer feature is frustoconical.

In various embodiments, the angle is between 20° to 30°.

In various embodiments, the first diameter being from about 1.5 to about 2 times the second diameter.

In various embodiments, a gas flow system having an internal passageway disposed therein is provided comprising a first portion of the internal passageway, a second portion of the internal passageway, a transition portion disposed between the first portion and the second portion, the transition portion being in fluid communication with the first portion and the second portion, the first portion having a first diameter and the second portion having a second diameter, the first diameter being from about one to about 3 times the second diameter.

In various embodiments, the transition portion includes a chamfer feature that is disposed at an angle between about 20 degrees and about 35 degrees from an outer wall of the second portion.

In various embodiments, a length of the transition portion is from about one to about three times the second diameter.

In various embodiments, the tombstone block is monolithic.

In various embodiments, the gas flow system further comprises a gasket at least partially surrounding the internal passageway.

In various embodiments, the chamfer feature extends about a circumference of the transition portion.

In various embodiments, the chamfer feature is frustoconical.

In various embodiments, the angle is between 20° to 30°.

In various embodiments, the first diameter being from about 1.5 to about 2 times the second diameter.

In various embodiments, a method is provided comprising drilling a first portion of an internal passageway in a monolithic block, drilling a transition portion of the internal passageway in the monolithic block, wherein the drilling is performed at an angle to an axial center of the transition portion so as to form a chamfer feature, drilling a second portion of the internal passageway in the monolithic block, the second portion in fluid communication with the transition portion an the first portion, the first portion having a first diameter and the second portion having a second diameter, the first diameter being from about one to about 3 times the second diameter.

In various embodiments, the angle is between about 20 degrees and about 35 degrees from an outer wall of the second portion.

In various embodiments, a length of the transition portion is from about one to about three times the second diameter.

In various embodiments, a length of the transition portion is from about one to about three times the second diameter.

These and other embodiments will become readily apparent to those skilled in the art from the following detailed description of certain embodiments having reference to the attached figures. The invention is not limited to any particular embodiment(s) disclosed.

### BRIEF DESCRIPTION OF THE DRAWING FIGURES

A more complete understanding of exemplary embodiments of the present disclosure can be derived by referring to the detailed description and claims when considered in connection with the following illustrative figures.

FIG. 1 illustrates a gas flow system according to various embodiments of the present disclosure.

FIG. 2 illustrates a gas flow system structure according to various embodiments of the present disclosure.

FIG. 3 illustrates a reactor system according to various embodiments of the present disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION

Although certain embodiments and examples are disclosed below, it will be understood that the invention extends beyond the specifically disclosed embodiments and/or uses of the invention and obvious modifications and equivalents thereof. Thus, it is intended that the scope of the invention disclosed should not be limited by the particular disclosed embodiments described below.

The present disclosure generally relates to systems and methods for dosing during a gas phase reaction process such as, for example, an atomic layer deposition (ALD) process, or other cyclical deposition process, though in various embodiments may find usefulness in a number of processes, including CVD, plasma-enhanced processes, etch processes, clean processes, and the like.

As used herein, the term substrate may refer to any underlying material or materials, including and/or upon which material can be deposited. A substrate can include a bulk material, such as silicon (e.g., single-crystal silicon), other Group IV materials, such as germanium, or compound semiconductor materials, such as GaAs, and can include one or more layers overlying or underlying the bulk material. For example, a substrate can include a patterning stack of several layers overlying bulk material. The patterning stack can vary according to application. Further, the substrate can include various gaps, such as recesses, vias, spaces between lines, trenches, and the like formed on the surface of the substrate.

In this disclosure, gas can include material that is a gas at normal temperature and pressure (NTP), a vaporized solid and/or a vaporized liquid, and can be constituted by a single gas or a mixture of gases, depending on the context. A gas other than a process gas, i.e., a gas introduced without passing through a gas distribution assembly, other gas distribution device, or the like, can be used for, e.g., sealing the reaction space, and can include a seal gas, such as a rare gas. In that regard, the a chemically inert gas may be flowed through the reaction chamber along with a process gas, i.e., a precursor containing gas. As used herein, “inert gas” may refer to a chemically inert gas such as the noble gases, or a relatively inert gas, such as nitrogen gas (N₂).

In this disclosure, any two numbers of a variable can constitute a workable range of the variable, and any ranges indicated may include or exclude the endpoints. Additionally, any values of variables indicated (regardless of whether they are indicated with about or not) may refer to precise values or approximate values and include equivalents, and may refer to average, median, representative, majority, or the like, in various embodiments. For example, the term about can refer to +/−20, 10, 5, 2, or 1 percent of a value. Further, in this disclosure, the terms including, comprising, constituted by and having and their equivalents can refer independently to typically or broadly comprising, consisting essentially of, or consisting of in some embodiments. In accordance with aspects of the disclosure, any defined meanings of terms do not necessarily exclude ordinary and customary meanings of the terms.

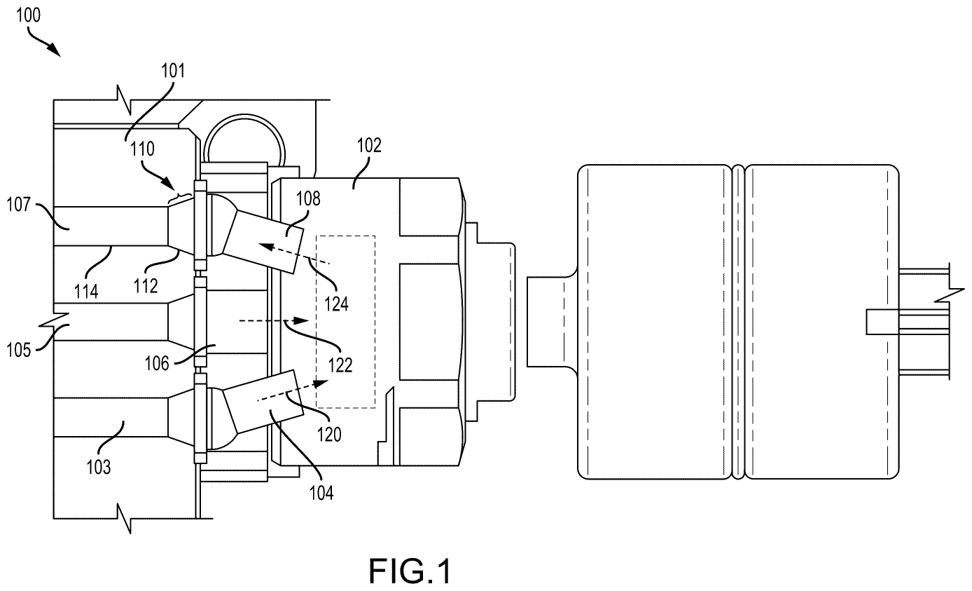

Turning now to the figures, FIG. 1 illustrates a gas flow system 100 in accordance with at least one embodiment of the disclosure. Gas flow system 100 includes a tombstone 102 and base block 101. Tombstone 102 and base block 101, in various embodiments, are monolithic. Base block 101 comprises passages therein that are configured to provide fluid communication between base block 101 and tombstone 102. Base bottom inlet 103 of base block 101 comprises a passage disposed in base block 101. Base middle inlet 105 of base block 101 comprises a passage disposed in base block 101. Base top outlet 107 of base block 101 comprises a passage disposed in base block 101. Each of base bottom inlet 103, base middle inlet 105, and base top outlet 107 may be drilled, machined, milled, bored, electrical discharge machined or otherwise formed in base block 101. In various embodiments, each of base bottom inlet 103, base middle inlet 105, and base top outlet 107 are formed during additive manufacturing of tombstone 102 and/or base block 101.

Tombstone 102 comprises passages therein that are configured to provide fluid communication between base block 101 and tombstone 102. Bottom inlet 104 of tombstone 102 comprises a passage disposed in tombstone 102. Middle inlet 106 of tombstone 102 comprises a passage disposed in tombstone 102. Top outlet 108 of tombstone 102 comprises a passage disposed in tombstone 102. Each of bottom inlet 104, middle inlet 106, and top outlet 108 may be drilled, machined, milled, bored, electrical discharge machined or otherwise formed in tombstone 102. Top outlet 108 and base top outlet 107 form an outlet passage, noting that the term passage and passageway are used herein interchangeably.

Tombstone 102 and base block 101 may be configured to be used with a reaction vessel configured as a CVD reactor, a cyclical deposition process reactor (e.g., a cyclical CVD reactor), an ALD reactor, a PEALD reactor, a cleaning chamber, or the like, any of which may include plasma apparatus, such as direct and/or remote plasma apparatus. The reaction vessel can be formed of suitable material, such as quartz, metal, or the like, and can be configured to retain one or more substrates for processing.

A source of precursor gas and an exhaust gas system may be in fluid communication with base block 101. Precursor gas, as used herein, is comprised of precursor materials in or substantially in a gaseous state. For example, various materials, such as carbon, hydrogen, and metals such as molybdenum may be present in the gaseous phase of precursor gas. Precursor gas may flow through base block 101 and into bottom inlet 104 and middle inlet 106. Exhaust flow may be drawn through top outlet 108 and return portion 114. Various precursors are at risk for leaving the gaseous state due to changes in temperature and/or pressure. In this manner, condensation and/or deposition of precursor material may form within tombstone 102 and/or base block 101. Such condensation and/or deposition of precursor material has a tendency to form where fluid flow changes travels through transitional zones of various volumes and interior surface features. In such areas, flow characteristics may tend to impart turbulence and/or encourage recirculation. In accordance with various embodiments, such tendency for condensation and/or deposition is decreased and/or eliminated.

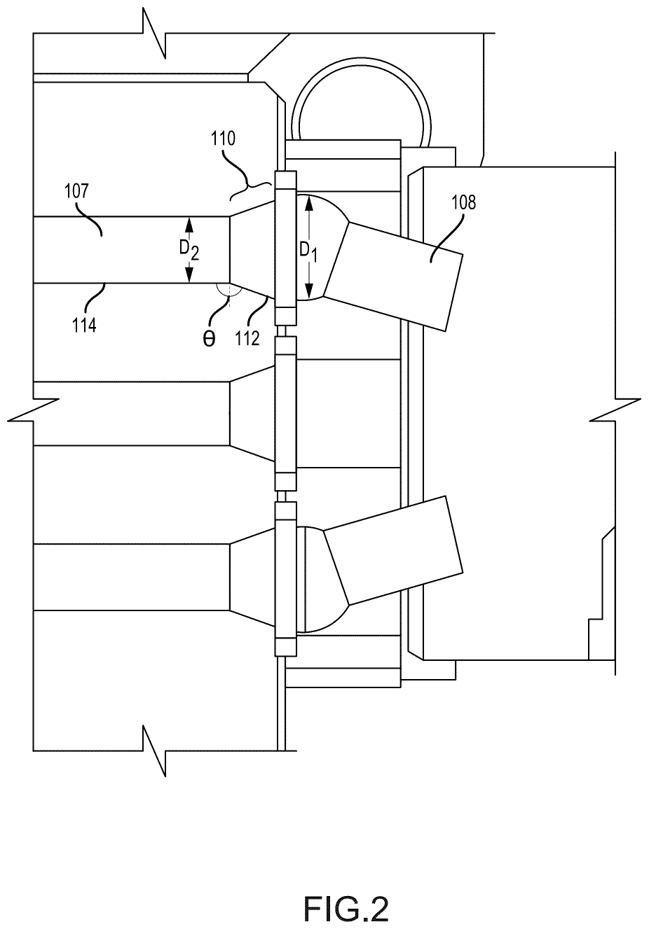

With reference to FIG. 2, transition portion 110 of top outlet 108 is shown in fluid communication with return portion 114. Return portion 114 is a cylindrical or substantially cylindrical shape with a constant diameter D2. Transition portion has an increasing diameter moving axially towards top outlet 108. Thus, in cross section, transition portion 110 may be frustoconical in shape. In this regard, the transition portion 110 may be referred to as a chamfer or chamfered feature. The chamfer feature may extend about a circumference of the transition portion 110. However, in cross section, transition portion 110 may take the form of additional geometries. The angle between a wall of return portion 114 and a wall of transition portion is angle q.

The angle q is, in various embodiments, important to the fluid flow dynamics within gas flow system 100. Too large an angle q may alter flow characteristics and tend to lead to undesirable condensation and/or deposition. Too small an angle q may affect package sizing and other variables. In various embodiments, angle q is between 105° to 125° and/or between 110° to 120°. Stated another way, an angle q as measured from a line parallel to D2 to transition portion 112, in various embodiments, is between 15° to 35° and/or between 20° to 30°. An angle q in this range tends to reduce turbulence in the flow, tends to avoid subsequent recirculation, and tends to improve flow characteristics to be more laminar than it otherwise would be at angle q values outside this range.

Another factor to enhancing flow characteristics is the ratio of D1 to D2. D1 is shown as the diameter of top outlet 108, representing an area proximate the transition from tombstone 102 to base block 101. D2 is shown as the diameter of return portion 114. As exhaust flow 124 moves through cross sectional area encompassed by D1 into the transition portion, the cross sectional volume decreases, affecting flow characteristics. In various embodiments, the ratio of D1 to D2 is from 3:1 to 1.1:1, and/or from 2.5:1 to 1.25:1, and/or from 2:1 to 1.5:1. Ratios of D1 to D2 within these ranges tends to reduce turbulence and subsequent recirculation.

The axial length of transition portion 110 may vary in response to the value of angle q. In this manner, larger values for angle q tend to increase the axial length of transition portion 110 while smaller values for angle q tend to decrease the axial length of transition portion 110. Moreover, the axial length of the transition portion, in various embodiments, is related to diameter D2. In various embodiments, the ratio of the axial length of the transition portion to diameter D2 is from 4:1 to 1:1, and/or from 2.5:1 to 1.5:1, and/or from 2:1 to 3:1. Ratios of the axial length of the transition portion to diameter D2 within these ranges tends to reduce turbulence and subsequent recirculation.

Gas flow system 100 may be constructed using any suitable method. For example, a method of fabrication may comprise drilling a first portion of an internal passageway in a monolithic block, drilling a transition portion of the internal passageway in the monolithic block, wherein the drilling is performed at an angle to an axial center of the transition portion so as to form a chamfer feature; drilling a second portion of the internal passageway in the monolithic block, the second portion in fluid communication with the transition portion an the first portion, the first portion having a first diameter and the second portion having a second diameter, the first diameter being from about one to about three times the second diameter.

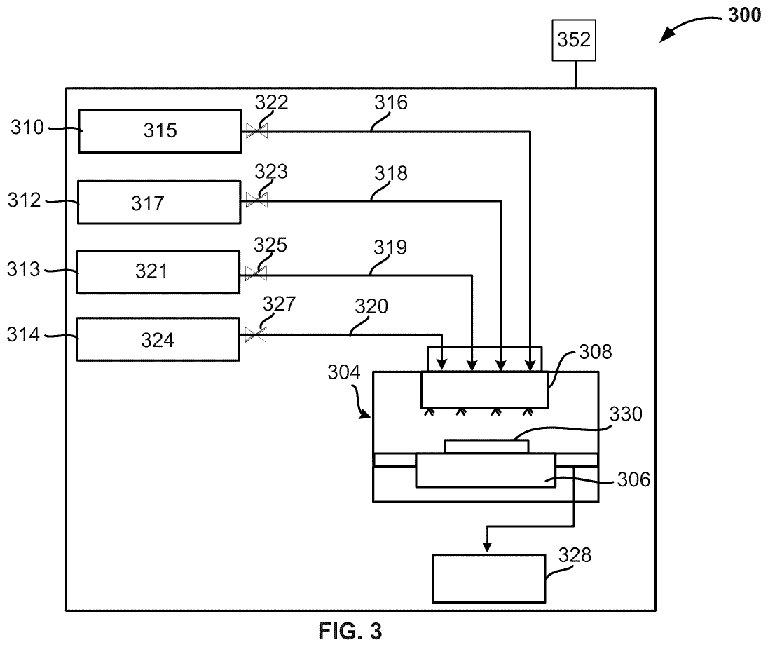

Turning now to FIG. 3, a gas flow system as disclosed herein may be used in connection with various reactor systems, for example, exemplary reactor system 300. Reactor system 300 includes a reaction chamber 304, a susceptor 306 to hold a substrate 330 during processing, a gas distribution system 308 (e.g., a showerhead) to distribute one or more blocking molecules, precursors and/or reactants to a surface of substrate 330, one or more blocking molecules, precursors, or reactant sources 310, 312, and/or 313, and/or a carrier and/or purge gas source 314, fluidly coupled to reaction chamber 304 via respective lines 316, 318, 319 and 320, and respective valves or controllers 322, 323, 325 and 327. Substrate 330 can include a substrate or structure as described herein. A purge/carrier gas 324 from gas source 314 can be flowed to and through reaction chamber 304 to act as a carrier gas, and/or purge or remove any excess blocking molecule, precursor, reactant or other undesired materials from reaction chamber 304. Sources 310, 312, and 313 can include vessels and blocking molecules, a precursor or a reactant as described herein. For example, source 310 can include a vessel and a blocking molecules 315; source 312 can include a vessel and precursor 317; source 313 can include a vessel and a reactant 321. Reactor system 300 can include additional sources. System 300 can also include a vacuum source 328 fluidly coupled to the reaction chamber 304. Vacuum source 328 can be configured to evacuate blocking molecules, precursors, reactants, a purge gas, byproducts, or other materials out of reaction chamber 304.

Reactor system 300 also includes a controller 352. Controller 352 can be configured to perform various functions and/or steps as described herein. Controller 352 can include one or more microprocessors, memory elements, and/or switching elements to perform the various functions. Although illustrated as a single unit, controller 352 can alternatively comprise multiple devices. Controller 352 can be used to control gas flow (e.g., by monitoring flow rates and controlling valves 322, 323, 325 and/or 327), motors, heaters, cooling devices and/or vacuum source 328 to execute various processes. Further, when a system includes two or more reaction chambers, the two or more reaction chambers can be coupled to the same/shared controller.

As noted above, example embodiments of the disclosure described above do not limit the scope of the invention, since these embodiments are merely examples of the embodiments of the invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

1. An outlet passage comprising:
a first portion having a first diameter and a second portion having a second diameter, the first diameter being from about one to about 3 times the second diameter;
a transition portion disposed between the first portion and the second portion;
the transition portion having a chamfer feature that is disposed at an angle between about 20 degrees and about 35 degrees from an outer wall of the second portion.

2. The outlet passage of claim 1, wherein a length of the transition portion is from about one to about three times the second diameter.

3. The outlet passage of claim 2, wherein the outlet passage is formed in a monolithic block.

4. The outlet passage of claim 3, further comprising a gasket at least partially surrounding the outlet passage.

5. The outlet passage of claim 3, wherein the chamfer feature extends about a circumference of the transition portion.

6. The outlet passage of claim 5, wherein the chamfer feature is frustoconical.

7. The outlet passage of claim 4, wherein the angle is between 20° to 30°.

8. The outlet passage of claim 4, wherein the first diameter being from about 1.5 to about 2 times the second diameter.

9. A tombstone block having an internal passageway disposed therein comprising:
a first portion of the internal passageway;
a second portion of the internal passageway;
a transition portion disposed between the first portion and the second portion, the transition portion being in fluid communication with the first portion and the second portion;
the first portion having a first diameter and the second portion having a second diameter, the first diameter being from about one to about 3 times the second diameter.

10. The tombstone block of claim 9, wherein the transition portion includes a chamfer feature that is disposed at an angle between about 20 degrees and about 35 degrees from an outer wall of the second portion.

11. The tombstone block of claim 10, wherein a length of the transition portion is from about one to about three times the second diameter.

12. The tombstone block of claim 11, wherein the tombstone block is monolithic.

13. The tombstone block of claim 12, further comprising a gasket at least partially surrounding the internal passageway.

14. The tombstone block of claim 13, wherein the chamfer feature extends about a circumference of the transition portion.

15. The tombstone block of claim 14, wherein the chamfer feature is frustoconical.

16. The tombstone block of claim 15, wherein the angle is between 20° to 30°.

17. The tombstone block of claim 16, wherein the first diameter being from about 1.5 to about 2 times the second diameter.

18. A method comprising:
drilling a first portion of an internal passageway in a monolithic tombstone block;
drilling a transition portion of the internal passageway in the monolithic tombstone block, wherein the drilling is performed at an angle to an axial center of the transition portion so as to form a chamfer feature;
drilling a second portion of the internal passageway in the monolithic tombstone block, the second portion in fluid communication with the transition portion and the first portion, the first portion having a first diameter and the second portion having a second diameter, the first diameter being from about one to about 3 times the second diameter.

19. The method of claim 18, wherein the angle is between about 20 degrees and about 35 degrees from an outer wall of the second portion.

20. The method of claim 19, wherein a length of the transition portion is from about one to about three times the second diameter.
